(19) United States
(12) Patent Application Publication
(10) Pub. No.: US 2010/0128625 A1
(43) Pub. Date: May 27, 2010

(54) Remote Control Method for Physical Layer Device and Related Physical Layer Device

(76) Inventors: Liang-Wei Huang, Taipei City (TW); Chun-Wen Yeh, Taipei County (TW); Chien-Sheng Lee, Miaoli County (TW); Tsung-Cheng Lee, Yunlin County (TW)

Correspondence Address: NORTH AMERICA INTELLECTUAL PROPERTY CORPORATION, P.O. BOX 506, MERRIFIELD, VA, 22116, US

(21) Appl. No.: 12/626,692

(22) Filed: Nov. 27, 2009

(30) Foreign Application Priority Data
Nov. 27, 2008 (TW) 097145890

(51) Int. Cl. H04L 12/26; H03M 13/00

(52) U.S. Cl. 370/252; 714/758

(57) ABSTRACT

A remote control method for a local physical layer device includes receiving a received packet, determining a coding of the received packet according to a packet format to generate a first determining result, determining an identification of the received packet according to the packet format to generate a second determining result, discarding the received packet according to the first determining result and the second determining result or decoding the received packet according to the packet format to generate a decoding result, and controlling or negotiating with a remote physical layer device according the decoding result.

### BACKGROUND OF THE INVENTION

1. Field of the Invention

The present invention relates to a remote control method and related device, and more particularly, to a method of remotely controlling or negotiating with a remote physical layer device.

2. Description of the Prior Art

Based on the specifications defined by the international organization for standard (ISO), the open system interconnection (OSI) model divides network architecture into seven layers which, from top to bottom, are an application layer, a presentation layer, a session layer, a transport layer, a network layer, link layer and a physical layer. In a communication device, the physical layer detects and receives packets. Then an upper layer, such as the link layer or the network layer, interprets the contents included in the packet. Generally, packets contain user data and parameters for each layer.

In a packet, controlling parameters, corresponding to the link layer (e.g. a media access control (MAC) layer), is used for controlling functions of the physical layer and detecting devices from a network, for example, rewriting data stored in a register of the physical layer or changing functions of the physical layer. However, the physical layer and the link layer usually are implemented in different chips. Moreover, even in the same communication device, parameters (e.g. chip identification number) are set in different ways since physical layer chips and link layer chips are manufactured by different manufacturers. In this situation, the link layer chips are not able to decode the packet received from the physical layer chips. This, therefore, is an obstacle to developments on communication products.

For example, communication devices A and B use the physical layer chips manufactured by company C and the link chips manufactured by D. When the communication device A sends the communication device B a packet, the sent packet includes the physical layer parameter settings from the company C. After the physical layer chip in the communication device B receives and detects the packet, the link layer chip in the communication device B starts decoding the packet. Since the link layer chip, manufactured by the company D, can not recognize the physical layer parameter settings from the company C, the packet sent by the communication device A, will be discarded.

According to the prior art, the physical layer only detects, receives, and uploads packets. After decoding the packets, upper layers command the physical layer to control corresponding functions of the physical layer. Thus, the local physical layer is not able to communicate with the remote physical layer directly. Controlling the physical layers can be achieved only by taking orders from upper layers.

### SUMMARY OF THE INVENTION

It is therefore an objective of the present invention to provide a method to control or negotiate with a remote physical layer for a local physical layer and provide a related physical layer device.

The present invention discloses a remote control method for a local physical layer to control or negotiate with a remote physical layer. The remote control method includes receiving a packet, determining a coding of the packet to generate a first determining result according to a packet format, determining an identification of the packet to generate a second determining result according to the packet format, discarding the packet according to the first determining result and the second determining result or decoding the packet to generate a decoding result according to a packet format, and controlling or negotiating with a remote physical layer according to the decoding result.

The present invention further discloses a physical layer device with function of controlling or negotiating with a remote physical layer. The physical layer device includes a receiver, a first determining unit, a second determining unit, a processing unit, and a control unit. The receiver is used for receiving a packet. The first determining unit is used for determining a coding of the packet to generate a first determining result. The second determining unit is used for determining an identification of the packet to generate a second determining result. The processing unit is used for discarding the packet according to the first determining result and the second determining result, or decoding the packet to generate a decoding result according to a packet format. The control unit is used for controlling or negotiating with a remote physical layer according the decoding result.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a physical layer device according to an embodiment of the present invention.

FIG. 2 is a schematic diagram of a packet format according to an embodiment of the present invention.

FIG. 3 is a flowchart of a process according to an embodiment of the present invention.

FIG. 4 is a flowchart of a process for a remote physical layer according to an embodiment of the present invention.

FIG. 5 is a flowchart of a process for a local physical layer according to an embodiment of the present invention.

### DETAILED DESCRIPTION

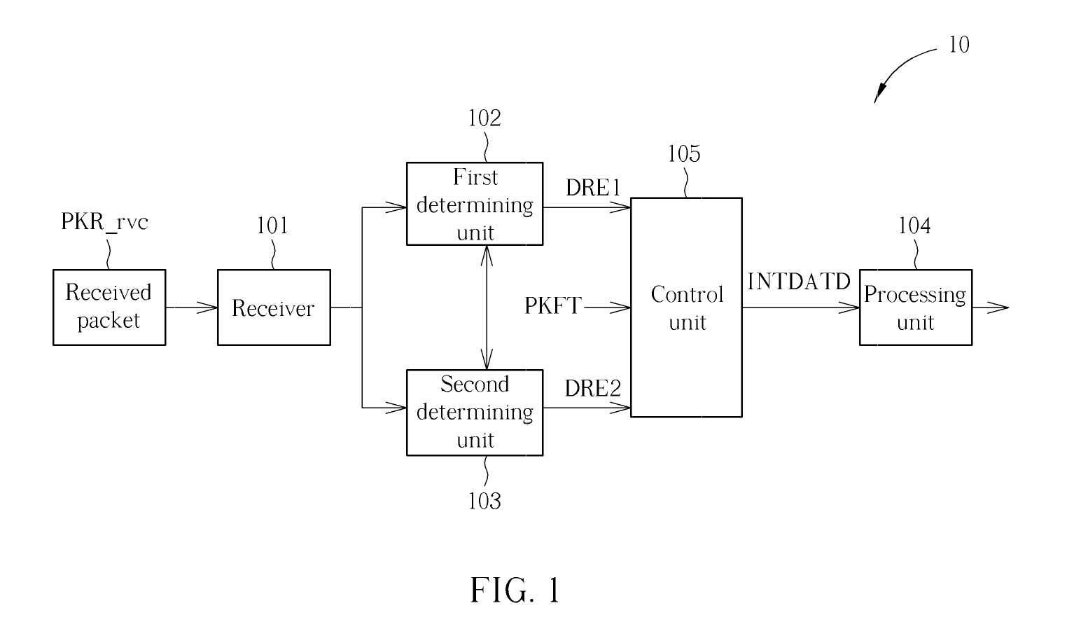

Please refer to FIG. 1, which is a schematic diagram of a physical layer device 10 according to an embodiment of the present invention. The physical layer device 10 is capable of controlling or negotiating with a remote physical layer. The physical layer device 10 includes a receiver 101, a first determining unit 102, a second determining unit 103, a control unit 104, and a processing unit 105. When the physical layer device 10 receives a packet PK_rcv from a remote physical device, the receiver 101 is in charge of receiving the packet PK_rcv. The first determining unit 102 determines a coding of the packet PK_rcv to generate a first determining result DRE1 according to the packet format PKFT. The second determining unit 103 determines an identification of the packet PK_rcv to generate a second result DRE2 according to a packet format PKFT. The processing unit 105 discards the packet PK_rcv according to the first determining result DRE1 and the second determining result DRE2, or decodes the packet PK_rcv to generate a decoding result INTDATA according to the packet format PKFT. The control unit 104 controls or negotiates with a remote physical layer according the decoding result INTDATA.

According to one of embodiments of the present invention, the physical layer device 10 is applied to an Ethernet. In this situation, the packet format PKFT is an Ethernet packet format. Regarding the coding determination, the first determining unit 102 checks if a cyclical redundancy check (CRC) code included in the packet PK_rcv is correct and generates the first determining result DRE1, according to the packet format PKFT. As for the identification determination, the second determining unit 103 checks an ether type of the packet PK_rcv to generate the second determining result DRE2, according to the packet format PKFT. When the first determining result DRE1 and the second determining result DRE2 both indicate that the coding and the identification of the packet PK_rcv are correct, this means that the packet PK_rcv can be decoded by the local physical layer. Then the processing unit 105 decodes the packet PK_rcv to generate the decoding result INTDATA according to the packet format PKFT. On the contrary, when either the first determining result DRE1 or the second determining result DREZ indicates that the coding or the identification of the packet PK_rcv is incorrect, the processing unit 105 discards the packet PK_rcv. Besides, the controlling signals are included in the other addresses of the packet format. For example, one specific bit denotes a signal to noise ration (SNR) information request and another specific bit denotes a SNR information response.

Please note that, the first determining unit 102, the second determining unit 103 and the control unit 104 can be realized by a hardware approach or a microprocessor, and not restricted herein. According to an embodiment of the present invention, the receiver 101 comprises a register for storing the packet PK_rcv.

The physical device 10 also receives packets sent by an upper layer device, such as a MAC layer device, and stores the packets in the receiver 101. According to an embodiment of the present invention, the physical layer device 10 takes actions corresponding to the packets sent from the remote physical layer, without interrupting the upper layer device to access the receiver 101. Right after the function of controlling or negotiating with a remote physical layer is completed, the packets stored in the receiver 101 are cleared.

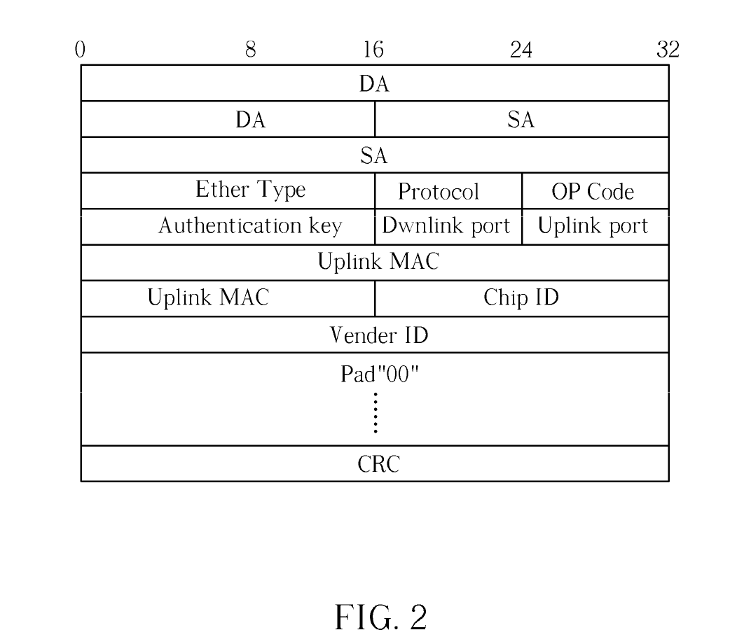

Please refer to FIG. 2, which is a schematic diagram of an Ethernet packet format 20 according to an embodiment of the present invention. The Ethernet packet format 20 can be the packet format PKFT shown in FIG. 1 and includes the Ethernet type and the CRC code for the packet identification and the packet coding, respectively. Those skilled in the art can set the Ethernet type. For example, when the local and the remote physical layer devices both consider “8899” a legal parameter for the Ethernet type, the identification is seen valid as long as the Ethernet type of the received packet is set to “8899”. Otherwise, the packet will be discarded. Similarly, according to the Ethernet packet format 20, the CRC code is exploited to confirm the coding of the packet. If the coding is incorrect, the packet is discarded as well.

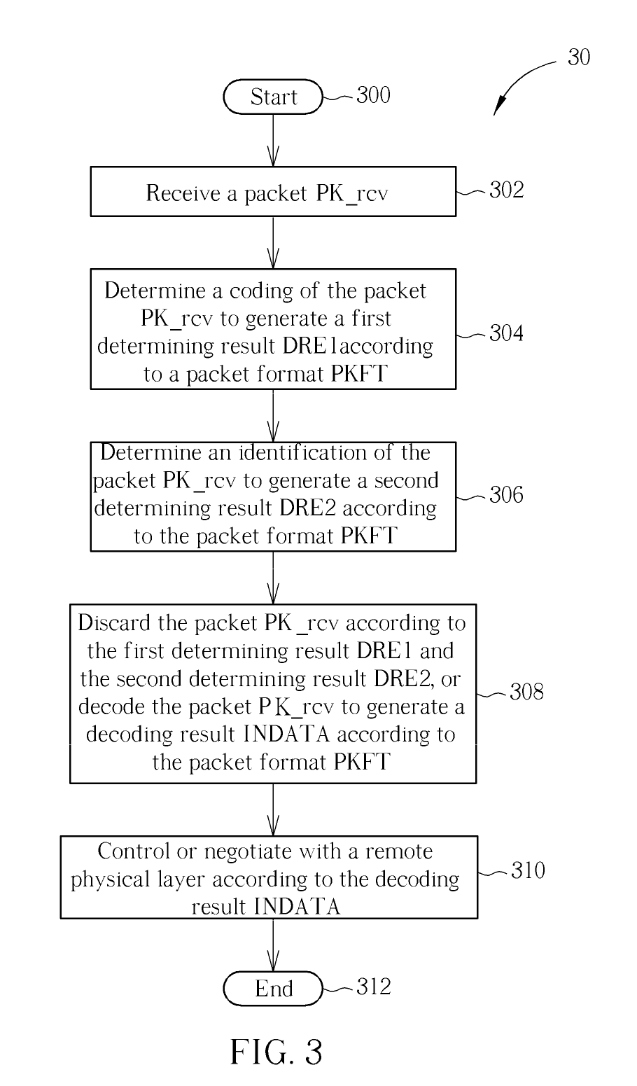

Furthermore, operations of the physical layer device 10 can be described in a process 30 shown in FIG. 3. The process 30 is used for a remote control for the local physical layer and includes the following steps:

Step 300: Start.

Step 302: Receive a packet PK_rcv.

Step 304: Determine a coding of the packet PK_rcv to generate a first determining result DRE1 according to a packet format PKFT.

Step 306: Determine an identification of the packet PK_rcv to generate a second result DRE2 according to the packet format PKFT.

Step 308: Discard the packet PK_rcv according to the first determining result DRE1 and the second determining result DRE2, or decode the packet PK_rcv to generate a decoding result INDATA according to the packet format PKFT.

Step 310: Control or negotiate with a remote physical layer according to the decoding result INDATA.

Step 312: End.

The process 30 states operations of the physical layer device 10. The detailed description is described above and thus not narrated herein. Hence, apart from receiving the packet, the local physical layer is able to decode controlling parameters included in the packet and control or negotiate with a remote physical layer directly.

In an embodiment of the present invention, functions of controlling or negotiating with a remote physical layer include a data swapping function and a management information of SNR. The control of the data swapping function is used for swapping data between a remote physical layer device and the physical layer device. The data swapping function includes: (1) replying to the remote physical layer device with register data of the physical layer device. (2) replying to the remote physical layer device that the register data of the physical layer device has been changed cannot be changed. (3) replying to the remote physical layer device that the register data of the physical layer device cannot be changed. (4) requesting the remote physical layer device to change its register data. (5) requesting the remote physical layer device to reply with its register data. The management information of SNR is described as follows: (1) requesting the remote physical layer device to reply with a SNR of the remote physical layer device. (2) replying to the remote physical layer device with a SNR of the physical layer device. In addiction, functions of controlling or negotiating with a remote physical layer further include: (1) requesting the remote physical layer device to reply with abilities of the remote physical layer device. (2) replying to the remote physical layer device with abilities of the physical layer device itself. (3) requesting the remote physical layer device to reduce abilities of the remote physical layer device. (4) requesting the remote physical layer device to enhance abilities of the remote physical layer device. (5) requesting the remote physical layer device to shut down. For example, when a transmission line is short, the physical layer device can request the remote physical layer device to close the channel coding for reduction of abilities of the physical layer. On the contrary, when the transmission line is long, the local physical layer can request the remote physical layer to perform higher linearity for enhancement of abilities of the physical layer. Moreover, when the local physical layer enters a standby mode with no data transmission, the remote physical layer may shut down for power saving.

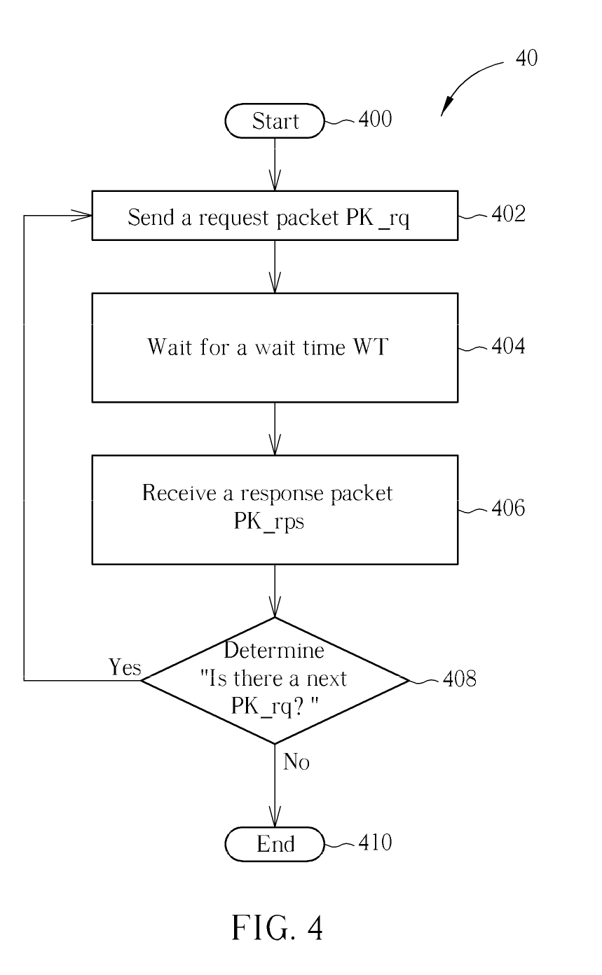

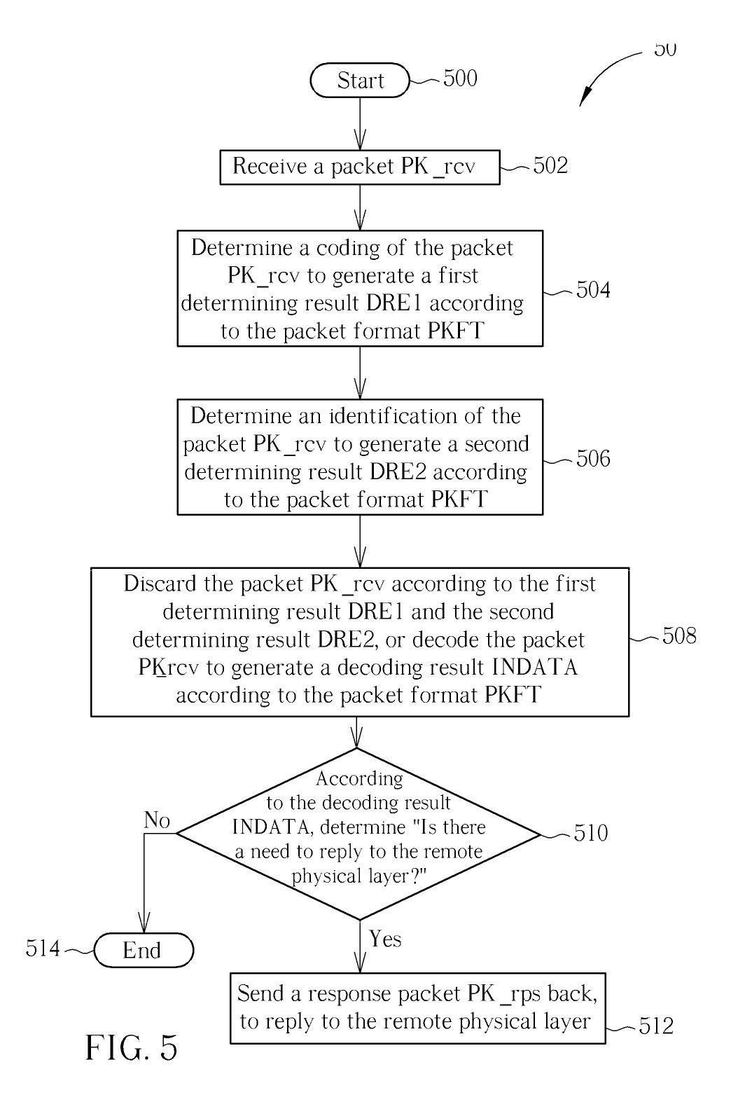

Please refer to FIG. 4 and FIG. 5. FIG. 4 is a flowchart of a process 40 for a remote physical layer device according to an embodiment of the present invention; FIG. 5 is a flowchart of a process 50 for a local physical layer device according to an embodiment of the present invention. FIG. 4 and FIG. 5 states that the local physical layer and the remote physical layer swap data by transmission and reception of packets. When the remote physical layer attempts to swap data with the local physical layer, the remote physical layer send a request packet PK_rq to the local physical layer. If there is any corresponding response from the local physical layer, the remote physical layer waits for and receives a response packet PK_rps sent by the local physical layer. When more than one data swappings are undertaken, the remote physical layer determines whether there is a next request or not. If so, the remote physical layer re-sends the request packet PK_rq. The process 40 is used for requesting data swapping with the local physical layer, for a remote physical layer. The process 40 includes the following steps:

Step 400: Start.

Step 402: Send a request packet PK_rq.

Step 404: Wait for a wait time WT.

Step 406: Receive a response packet PK_rps.

Step 408: Determine “Is there a next PK_rq?”, If yes, then go to step 402. Otherwise, go to Step 410.

Step 410: End.

When receiving a packet from the remote physical layer, the local physical layer determines the coding and the identification of the packet PK_rcv according to the packet format PKFT. When the coding and the identification both are correct, the local physical layer is able to decode the packet PK_rcv and accordingly make a response based on decoded data. For example, the remote physical layer sends the request packet PK_rq, requesting the local physical layer to reply with data stored in the register. When the local physical layer receives the packet and determines the coding and the identification are valid, the local physical layer starts decoding and sends the remote physical layer a response packet PK_rps for data swapping, after decoding. The process 50 states the local physical layer accordingly takes some actions to respond to the remote physical layer after receiving the packet PK_rcv. The process 50 includes the following steps:

Step 500: Start.

Step 502: Receive a packet PK_rcv.

Step 504: Determine a coding of the packet PK_rcv to generate a first result DRE1 according to the packet format PKFT.

Step 506: Determine an identification of the packet PK_rcv to generate a second result DRE2 according to the packet format PKFT.

Step 508: Discard the packet PK_rcv according to the first determining result DREZ and the second determining result DRE2, or decode the packet PK_rcv to generate a decoding result INDATA according to the packet format PKFT.

Step 510: According to the decoding result INDATA, determine “Is there a need to reply to the remote physical layer?” If yes, then go to Step 512. Otherwise, go to Step 514.

Step 512: Send a response packet PK_rps back, to reply to the remote physical layer.

Step 514: End.

Thus, according to the processes 40 and 50, the remote physical layer requests the local physical layer to reply with corresponding information or controls functions of the local physical layer, by sending the request packet. The local physical layer accordingly responds by sending the response packet as well.

According to the prior art, the physical layer can detect and receive packets only. The received packet must be decoded by upper layers. That is, functions of the physical layer can be controlled only via upper layers. According to an embodiment of the present invention, apart from packet detection and reception, the physical layer is able to obtain control parameters related to functions of the remote physical layer. Therefore, the present invention can realize a remote control between the physical layers.

Those skilled in the art will readily observe that numerous modifications and alterations of the device and method may be made while retaining the teachings of the invention.

What is claimed is:

1. A physical layer device, comprising:
a receiver, for receiving a packet;
a first determining unit, coupled to the receiver, for determining a coding of the packet to generate a first determining result;
a second determining unit, coupled to the receiver, for determining an identification of the packet to generate a second determining result;
a processing unit, for discarding the packet according to the first determining result and the second determining result, or decoding the packet to generate a decoding result according to a packet format; and
a control unit, for controlling or negotiating with a remote physical layer device according the decoding result.

2. The physical layer device of claim 1, wherein the first determining unit checks a cyclical redundancy check (CRC) code of the packet according to the packet format.

3. The physical layer device of claim 1, wherein the second determining unit checks an ether type of the packet according to the packet format.

4. The physical layer device of claim 1, wherein the packet format is an Ethernet packet format.

5. The physical layer device of claim 1, wherein the physical layer device further comprises a register storing a register data, and wherein the control unit performs at least one of:
replying to the remote physical layer device with the register data;
replying to the remote physical layer device that the register data has been changed;
replying to the remote physical layer device that the register data cannot be changed;
requesting the remote physical layer device to change its register data; and
requesting the remote physical layer device to reply with its register data.

6. The physical layer device of claim 1, wherein the control unit performs at least one of:
requesting the remote physical layer device to reply with a SNR value of the remote physical layer device; and
replying to the remote physical layer device with a SNR value of the physical layer device.

7. The physical layer device of claim 1, wherein the control unit performs at least one of:
requesting the remote physical layer device to reply with abilities of the remote physical layer device;
replying to the remote physical layer device with abilities of the physical layer device;
requesting the remote physical layer device to reduce the abilities of the remote physical layer device;
requesting the remote physical layer device to enhance the abilities of the remote physical layer device; and
requesting the remote physical layer device to shut down.

8. The physical layer device of claim 1, wherein when the first determining result indicates that the coding of the packet is correct and the second determining result indicates that the identification of the packet is correct, the control unit performs controlling or negotiating with a remote physical layer device.

9. The physical layer device of claim 1, wherein the first determining unit checks whether a cyclical redundancy check code included in the packet is correct so as to generate the first determining result.

10. The physical layer device of claim 1, wherein the second determining unit checks whether an ether type of the packet is correct so as to generate the second determining result.

11. The physical layer device of claim 1, wherein when the first determining result and the second determining result are correct, the control unit requests the remote physical layer device to change its register data.

12. The physical layer device of claim 1, wherein when the first determining result and the second determining result are correct, the control unit requests the remote physical layer device to reply with a SNR value of the remote physical layer device.

13. A remote control method for a physical layer device, the remote control method comprising:
receiving a packet;
determining a coding of the packet to generate a first determining result according to a packet format;
determining an identification of the packet to generate a second determining result according to the packet format;
discarding the packet according to the first determining result and the second determining result, or decoding the packet to generate a decoding result according to the packet format; and
controlling or negotiating with a remote physical layer device according the decoding result.

14. The remote control method of claim 13, wherein the step of determining the coding of the packet according to the packet format comprises checking a cyclical redundancy check (CRC) code according to the packet format.

15. The remote control method of claim 13, wherein the step of determining the identification of the packet according to the packet format comprises checking an ether type of the packet according to the packet format.

16. The remote control method of claim 13, wherein the packet format is an Ethernet packet format.

17. The remote control method of claim 13, wherein the step of controlling or negotiating with the remote physical layer device according the decoding result comprises at least one of:
replying to the remote physical layer device with a register data of the physical layer device;
replying to the remote physical layer device that the register data of the physical layer device has been changed;
replying to the remote physical layer device that the register data of the physical layer device cannot be changed;
requesting the remote physical layer device to change its register data; and
requesting the remote physical layer device to reply with its register data.

18. The remote control method of claim 13, wherein the step of controlling or negotiating with the remote physical layer device according the decoding result comprises at least one of:
requesting the remote physical layer device to reply with a SNR value of the remote physical layer device; and
replying to the remote physical layer device with a SNR value of the physical layer device.

19. The remote control method of claim 13, wherein the step of controlling or negotiating with the remote physical layer device according the decoding result comprises at least one of:
requesting the remote physical layer device to reply with abilities of the remote physical layer device;
replying to the remote physical layer device with the abilities of the physical layer device;
requesting the remote physical layer device to reduce abilities of the remote physical layer device;
requesting the remote physical layer device to enhance abilities of the remote physical layer device; and
requesting the remote physical layer device to shut down.

20. The remote control method of claim 13, wherein the step of controlling or negotiating with the remote physical layer device according the decoding result comprises:
obtaining a control parameter of the remote physical layer device.
